(19) United States
(12) Patent Application Publication
(10) Pub. No.: US 2026/0150702 A1
(43) Pub. Date: May 28, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Tetsuo TAKAHASHI, Tokyo (JP); Yosuke NAKATA, Tokyo (JP)

(73) Assignee: Mitsubishi Electric Corporation, Tokyo (JP)

(21) Appl. No.: 19/346,791

(22) Filed: Oct. 1, 2025

(30) Foreign Application Priority Data
Nov. 26, 2024 (JP) 2024-205494

(51) Int. Cl. H01L 23/544; H01L 23/00; H10D 30/66; H10D 62/10; H10D 62/832

(52) U.S. Cl. CPC H10W 46/00; H10D 30/665; H10D 30/668; H10D 62/107; H10D 62/8325; H10W 42/00; H10W 42/121; H10W 46/503

(57) ABSTRACT

A semiconductor device includes a semiconductor element having a semiconductor substrate in which an active region through which a main current flows, a termination region which is a region on an outer peripheral side of the active region, and a dicing line region which is a region on an outer peripheral side of the termination region are defined. A metal pattern is provided on an upper surface of the semiconductor substrate in the dicing line region, and the metal pattern is arranged in the dicing line region and is not arranged in at least one corner portion of the dicing line region.

### BACKGROUND

### Technical Field

The present disclosure relates to a semiconductor device and a method of manufacturing the semiconductor device.

### Description of the Background Art

A switching element for controlling power supply such as a motor load is mounted on a power semiconductor device generally called a power device. As a switching element, an insulated gate semiconductor element such as a metal oxide semiconductor field effect transistor (MOSFET) or an insulated gate bipolar transistor (IGBT) is widely used.

High current, high voltage, and low loss have been advanced in power semiconductor devices, and they are used in various fields. The power semiconductor devices are often used in harsh environments such as highland, high temperature, and high humidity environments, and high reliability such as temperature cycle and moisture resistance is required in addition to low loss. Furthermore, these characteristics are required to be realized at low cost.

These power semiconductor devices are generally manufactured by using a method such as lithography, etching, or deposition of a semiconductor wafer using silicon (Si) as a semiconductor material, but in recent years, high-performance semiconductor devices using a semiconductor wafer using a wide band gap semiconductor such as silicon carbide (SiC) as a semiconductor material have also been manufactured.

After a series of manufacturing steps of the semiconductor element described above is completed, individual semiconductor elements are cut out by a dicing step and assembled into a module or the like, and the manufacturing step is completed.

In the manufacturing step of the semiconductor element described above, an alignment pattern of the semiconductor wafer, a film thickness measurement pattern at the time of manufacturing, and the like are required, and these patterns are generally arranged on the semiconductor wafer. However, when these patterns are arranged on a dicing line, a problem may occur at the time of dicing.

As a countermeasure against such a problem, for example, Japanese Patent Application Laid-Open No. 2015-106693 discloses a technique in which a metal mark is not arranged at the center of a dicing line so that the metal mark does not block laser light and does not inhibit dicing at the time of laser dicing.

In addition, for example, Japanese Patent Application Laid-Open No. 2010-129695 discloses a technique of suppressing generation of foreign matter and the like at the time of dicing by forming a dedicated pattern in a semiconductor element region between a withstand voltage holding region and a dicing line.

However, the technique described in Japanese Patent Application Laid-Open No. 2015-106693 discloses an example in which a pattern is arranged on a dicing line including an intersection portion of the dicing line that affects peeling of a mold resin. In particular, when the pattern is arranged at the intersection portion of the dicing lines, a locally strong stress is applied to the intersection portion of the dicing lines where the pattern is arranged, that is, the corner portion of the semiconductor element, so that there is a possibility that the mold resin is peeled off from the pattern as a starting point.

Similarly, in the technique described in Japanese Patent Application Laid-Open No. 2010-129695, when a pattern is arranged at a corner portion of a semiconductor element region, there is a possibility that the mold resin is peeled off from the pattern as a starting point.

### SUMMARY

An object of the present disclosure is to provide a technique capable of suppressing peeling of a mold resin from a reference pattern for manufacturing as a starting point in a semiconductor device.

A semiconductor device according to the present disclosure includes a semiconductor element. The semiconductor element includes a semiconductor substrate in which an active region through which a main current flows, a termination region which is a region on an outer peripheral side of the active region, and a dicing line region which is a region on an outer peripheral side of the termination region are defined. A manufacture-time reference metal pattern is provided on an upper surface of the semiconductor substrate in the dicing line region. The manufacture-time reference metal pattern is arranged in the dicing line region and is not arranged in at least one corner portion of the dicing line region.

A locally strong stress is suppressed from being applied to at least one corner portion of the dicing line region, that is, at least one corner portion of the semiconductor element. As a result, it is possible to suppress the manufacture-time reference metal pattern from becoming a starting point of peeling of the mold resin.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor wafer on which a semiconductor element included in a semiconductor device according to a first preferred embodiment is formed;

FIG. 2 is a top view of the semiconductor element included in the semiconductor device according to the first preferred embodiment;

FIG. 3 is an enlarged view of a region 202 in FIG. 1;

FIG. 4 is a cross-sectional view taken along line A-A′ in FIG. 2;

FIG. 5 is a cross-sectional view taken along line B-B′ in FIG. 2;

FIG. 6 is a cross-sectional view taken along line C-C′ in FIG. 2;

FIG. 7 is a cross-sectional view of an end portion of the semiconductor device for explaining the effect of the first preferred embodiment;

FIG. 8 is a top view of the semiconductor device for explaining the effect of the first preferred embodiment;

FIG. 9 is a top view of a semiconductor element included in a semiconductor device according to a second preferred embodiment;

FIG. 10 is an enlarged view corresponding to a region 202 in FIG. 1 in the second preferred embodiment;

FIG. 11 is a cross-sectional view taken along line D-D′ in FIG. 9;

FIG. 12 is a cross-sectional view taken along line E-E′ in FIG. 9;

FIG. 13 is a cross-sectional view taken along line F-F′ in FIG. 9;

FIG. 14 is a top view of a semiconductor element included in a semiconductor device according to a third preferred embodiment;

FIG. 15 is an enlarged view corresponding to the region 202 in FIG. 1 in the third preferred embodiment;

FIG. 16 is a cross-sectional view taken along line G-G′ in FIG. 14;

FIG. 17 is a cross-sectional view taken along line H-H′ in FIG. 14;

FIG. 18 is a cross-sectional view taken along line I-I′ in FIG. 14;

FIG. 19 is a top view of a semiconductor element included in a semiconductor device according to a fourth preferred embodiment;

FIG. 20 is a cross-sectional view taken along line J-J′ in FIG. 19;

FIGS. 21A and 21B are cross-sectional views of a semiconductor element included in a semiconductor device according to a first modification of the fourth preferred embodiment; and

FIG. 22 is a cross-sectional view of a semiconductor element included in a semiconductor device according to a second modification of the fourth preferred embodiment.

### DESCRIPTION OF THE PREFERRED EMBODIMENTS

### First Preferred Embodiment

A first preferred embodiment will be described below with reference to the drawings. A top view of a semiconductor wafer 200 on which a semiconductor element 100 included in a semiconductor device according to the first preferred embodiment is formed is illustrated.

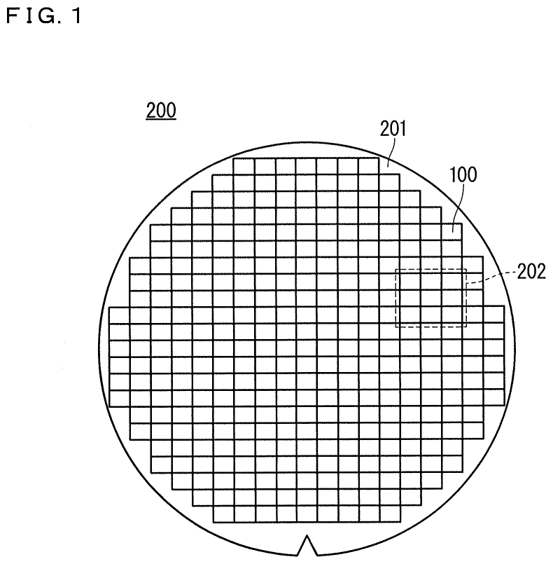

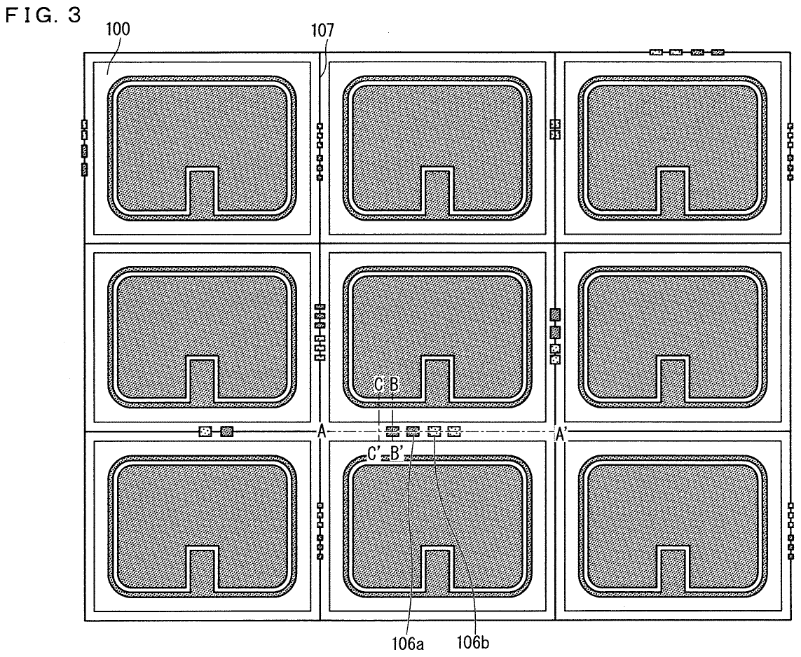

As illustrated in FIG. 1, the semiconductor wafer 200 is cut in the longitudinal direction and the lateral direction along a plurality of dicing lines 107 (see FIG. 3) in a wafer region 201. A plurality of semiconductor elements 100 cut out by dicing is formed on the semiconductor wafer 200. Here, the longitudinal direction and the lateral direction are the longitudinal direction and the lateral direction of the paper surface in FIG. 1.

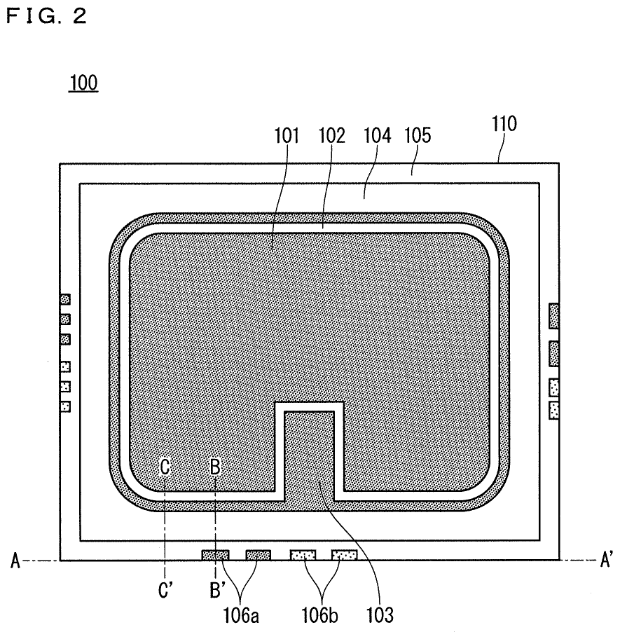

FIG. 2 is a top view of the semiconductor element 100 included in the semiconductor device according to the first preferred embodiment. FIG. 3 is an enlarged view of a region 202 in FIG. 1. FIG. 2 illustrates the semiconductor element 100 cut out by dicing. As illustrated in FIG. 2, the semiconductor element 100 includes a semiconductor substrate 110. In the semiconductor substrate 110, an active region 101, a gate pad region 103, a termination region 104, and a dicing line region 105 are defined.

The active region 101 is a region through which a main current flows. In the active region 101, a source electrode 11 (see FIG. 5), which is one of the main electrodes, is formed. The gate pad region 103 extends from the central portion of one side of the active region 101 toward the central portion of the active region 101. An annular gate wiring 102 is provided along the outer peripheral portion of the active region 101. The gate wiring 102 is connected to the gate pad region 103. The termination region 104 is a region on the outer peripheral side of the active region 101, and is formed so as to surround the active region 101, the gate wiring 102, and the gate pad region 103 in order to maintain the withstand voltage. The dicing line region 105 is a region on the outer peripheral side of the termination region 104.

On the upper surface of the semiconductor substrate 110 in the dicing line region 105, a metal pattern 106a as a manufacture-time reference metal pattern and a groove pattern 106b as a manufacture-time reference pattern are provided. The metal pattern 106a is a film stacked from the surface of the semiconductor substrate 110 by deposition, sputtering, or the like in a metal step of forming wiring. The groove pattern 106b is a groove formed by etching the semiconductor substrate 110. In the first preferred embodiment, after the groove pattern 106b is formed in the etching step, the metal pattern 106a is formed in the metal step.

Here, the metal pattern 106a and the groove pattern 106b are a pattern used for alignment for arranging the semiconductor wafer 200 at a predetermined position on the stage in the manufacturing step of the semiconductor element 100, a pattern used for detailed overlapping of lithography, an inspection mark, or a pattern for measuring the film thickness in the manufacturing process of the semiconductor element 100 or the like, or for confirming electrical characteristics. Since shapes of the metal pattern 106a and the groove pattern 106b vary depending on a purpose and a manufacturing step, detailed shapes of the metal pattern 106a and the groove pattern 106b are not illustrated and are illustrated in a simple pattern.

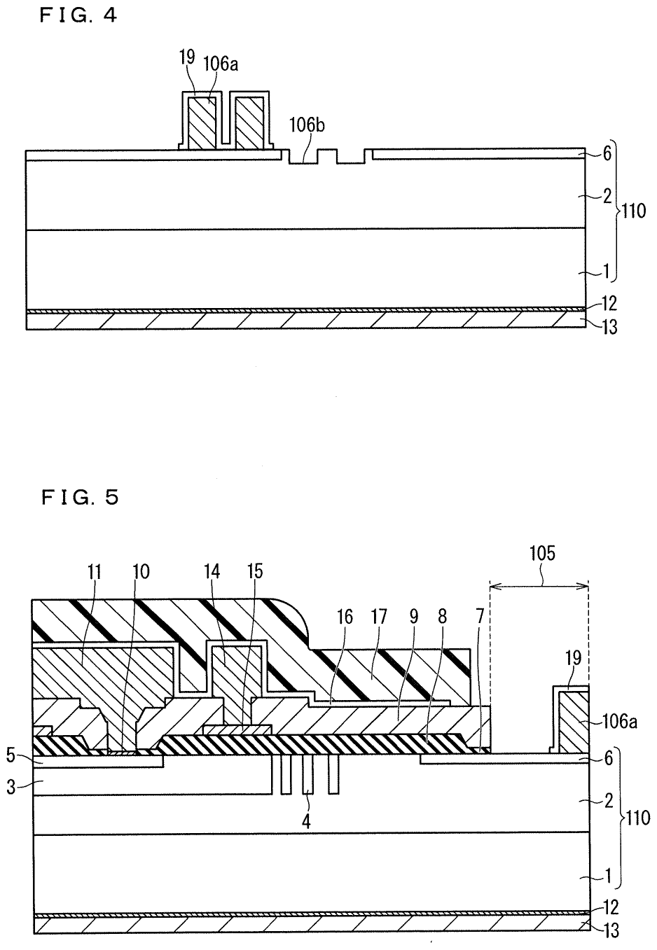

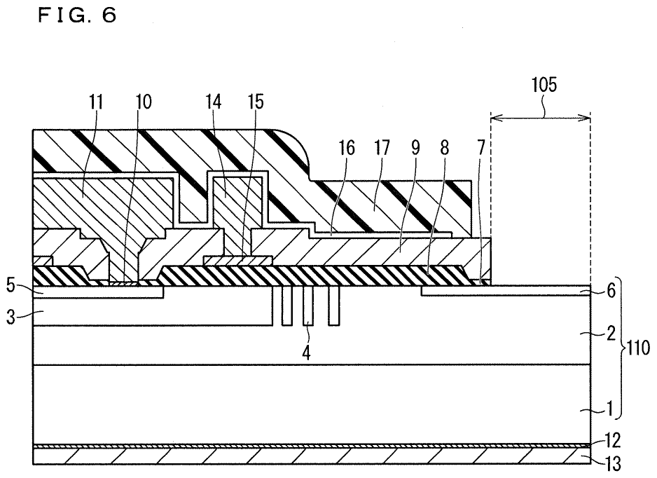

Next, a cross-sectional structure of the semiconductor element 100 will be described. FIG. 4 is a cross-sectional view taken along line A-A′ in FIG. 2, and illustrates a cross section of the dicing line region 105 cut out in a cross section parallel to the dicing line 107 (see FIG. 3). FIG. 5 is a cross-sectional view taken along line B-B′ in FIG. 2, and illustrates a cross section of a region including the metal pattern 106a. FIG. 6 is a cross-sectional view taken along line C-C′ in FIG. 2, and illustrates a cross section of a region not including the metal pattern 106a and the groove pattern 106b.

As illustrated in FIGS. 4 to 6, the semiconductor substrate 110 includes an n⁺substrate 1, an n⁻ drift layer 2 provided on an upper surface of the n⁺ substrate 1, and a p well layer 3, a pFLR layer 4, a p⁺ contact layer 5, and an n-channel stopper layer 6 provided in the n⁻ drift layer 2. On the lower surface of the semiconductor substrate 110, a drain electrode 13 is provided via a silicide layer 12.

In the paper surfaces of FIGS. 5 and 6, the region on the left side of the dicing line region 105 is the termination region 104 (see FIG. 2) from the end portion of the active region 101 (see FIG. 2). The same applies to FIGS. 12, 13, 17, 18, 20, 21A, 21B, and 22 described below.

As illustrated in FIGS. 5 and 6, the end portion of the active region 101 and the gate wiring 102 (see FIG. 2) are provided on the upper side of the p well layer 3. The termination region 104 forms a withstand voltage holding structure including the pFLR layer 4 and the n-channel stopper layer 6, and an underlay insulating film 7, a field insulating film 8, and an interlayer insulating film 9 are provided on the upper side thereof. The interlayer insulating film 9 is covered with an insulating film 16 made of a silicon nitride film and an organic protective film 17 made of polyimide. Note that the insulating film 16 may be made of a silicon oxide film. Furthermore, the organic protective film 17 may be made of polyamide.

As illustrated in FIGS. 5 and 6, at the end portion of the active region 101, the source electrode 11 is provided on the field insulating film 8 via a silicide layer 10. In addition, a gate electrode 14 is provided on the field insulating film 8 via a gate wire 15. The source electrode 11 and the gate electrode 14 are also covered with the insulating film 16 and the organic protective film 17.

As illustrated in FIG. 4, in the first preferred embodiment, the upper surface of the semiconductor substrate 110 is exposed in the dicing line region 105, and the metal pattern 106a and the groove pattern 106b are partially arranged on the exposed upper surface of the semiconductor substrate 110. The metal pattern 106a is formed in a step shape protruding upward from the upper surface of the semiconductor substrate 110. The metal pattern 106a is covered with a protective film 19. Here, in FIGS. 2 and 3, illustration of the protective film 19 covering the metal pattern 106a is omitted.

Note that a structure called a planar MOSFET or a trench MOSFET is adopted as the semiconductor element 100, but the structure of the active region 101 is not a part related to the features of the first preferred embodiment, and thus the details of the active region 101 are omitted.

Furthermore, in the first preferred embodiment, the semiconductor element 100 can be manufactured by using a general technique such as lithography, etching, or deposition, and thus details of the manufacturing method are omitted.

A first feature of the first preferred embodiment is that the metal pattern 106a and the groove pattern 106b are arranged in the dicing line region 105 and are not arranged in at least one corner portion (more specifically, four corner portions) of the dicing line region 105.

A second feature of the first preferred embodiment is that the metal pattern 106a and the groove pattern 106b are arranged in the linear portion of the dicing line region 105. Here, the linear portion of the dicing line region 105 is a portion having a linear shape that connects the corner portions of the dicing line region 105.

A third feature of the first preferred embodiment is that the metal pattern 106a is covered with the protective film 19.

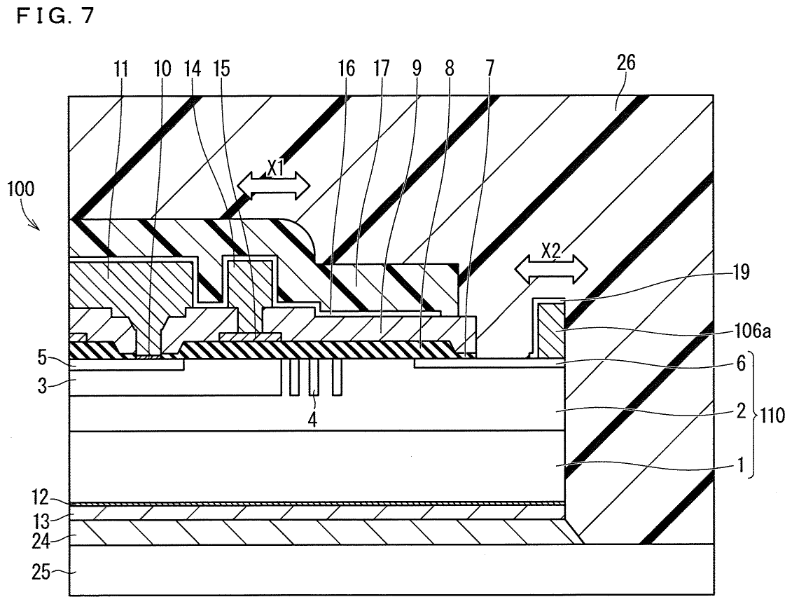

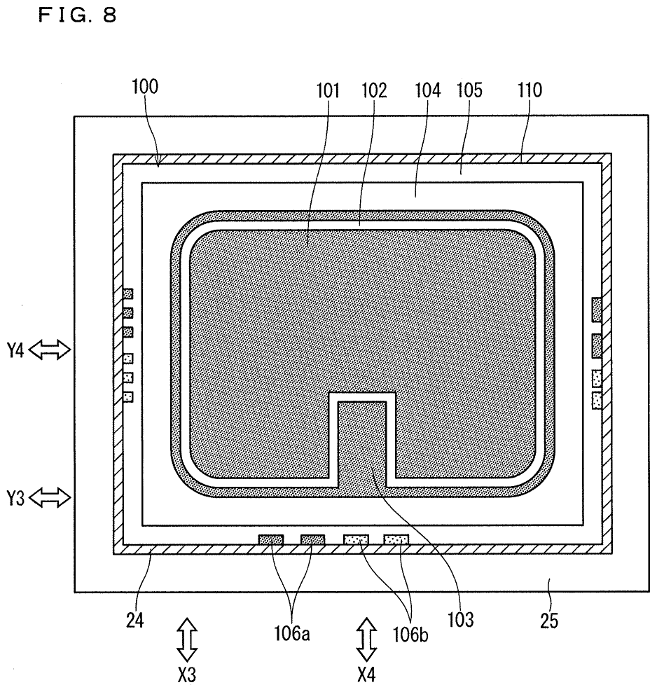

Next, features and effects of the first preferred embodiment will be described with reference to FIGS. 7 and 8. FIG. 7 is a cross-sectional view of an end portion of the semiconductor device for explaining the effect of the first preferred embodiment. FIG. 8 is a top view of the semiconductor device for explaining the effect of the first preferred embodiment.

As illustrated in FIG. 7, the semiconductor device includes the semiconductor element 100, a base substrate 25, and a mold resin 26. The base substrate 25 is bonded to the lower surface of the semiconductor element 100 via a bonding layer 24 such as solder. An upper surface and a side surface of the semiconductor element 100 are sealed with the mold resin 26.

In the semiconductor device for mold sealing, since the respective materials constituting the semiconductor element 100, the base substrate 25, and the mold resin 26 have different linear expansion coefficients, stresses X1 and X2 are generated at the respective interfaces for reasons such as a change in environmental temperature to be used or a temperature rise due to energization.

In particular, at the interface between the mold resin 26 and the semiconductor element 100, stress tends to increase due to a difference in linear expansion coefficient between the mold resin 26 and the semiconductor element 100 and a difference in size between the semiconductor element 100 and the mold resin 26 that stores and seals the semiconductor element 100. Therefore, peeling of the mold resin 26 progresses from the end portion of the dicing line region 105, and ingress of moisture or the like occurs, so that the moisture resistance of the semiconductor device is likely to deteriorate.

As illustrated in FIG. 8, the magnitude of the stress varies depending on the position of the semiconductor element 100, and stress X4 or Y4 in one direction is applied to the linear portion, whereas stresses X3 and Y3 are two-dimensionally applied to the corner portion from the lateral direction and the longitudinal direction, so that peeling of the mold resin 26 is likely to proceed from the corner portion. Here, the horizontal direction and the vertical direction are the horizontal direction and the vertical direction of the paper surface in FIG. 8.

Here, how the metal pattern 106a and the groove pattern 106b affect will be considered with reference to FIGS. 5 and 6. The sizes or shapes of the metal pattern 106a and the groove pattern 106b are limited by pattern recognition capability or alignment accuracy of a semiconductor device manufacturing apparatus (not illustrated). As an example, there is a case where a non-target pattern having a predetermined size and a step for recognizing the metal pattern 106a and the groove pattern 106b, or a uniform pattern in a certain area is required to improve measurement accuracy.

Since the vicinity of such a pattern is likely to be a starting point of peeling of the mold resin 26, it is not preferable to arrange the pattern in a region where stress is strong.

In particular, aluminum wiring or copper wiring is often used in the manufacturing step of the semiconductor device, and in a case where it is necessary to form a pattern using these metals, when the pattern is arranged in a region where stress is strong, the shape of the pattern is deformed due to corrosion of the metal, and thus, there arises a problem that peeling of the mold resin 26 is accelerated.

On the other hand, in the first preferred embodiment, the semiconductor device includes the semiconductor element 100 having the semiconductor substrate 110 in which the active region 101 through which the main current flows, the termination region 104 which is a region on the outer peripheral side of the active region 101, and the dicing line region 105 which is a region on the outer peripheral side of the termination region 104 are defined. The metal pattern 106a is provided on the upper surface of the semiconductor substrate 110 in the dicing line region 105, and the metal pattern 106a is arranged in the dicing line region 105 and is not arranged in at least one corner portion of the dicing line region 105.

In addition, the groove pattern 106b is further provided on the upper surface of the semiconductor substrate 110 in the dicing line region 105. The groove pattern 106b is arranged in the dicing line region 105 and is not arranged in at least one corner portion of the dicing line region 105.

More specifically, both the metal pattern 106a and the groove pattern 106b are not arranged at the four corner portions of the dicing line region 105, but are arranged at the linear portions of the dicing line region 105.

Therefore, a locally strong stress is suppressed from being applied to the corner portion of the dicing line region 105, that is, the corner portion of the semiconductor element 100. As a result, it is possible to suppress the metal pattern 106a and the groove pattern 106b from becoming a starting point of peeling of the mold resin 26. As a result, reliability such as moisture resistance of the semiconductor device can be improved without taking special measures such as increasing the size of the semiconductor element 100.

Furthermore, the metal pattern 106a is formed in a step shape protruding upward from the upper surface of the semiconductor substrate 110. In addition, since the metal pattern 106a is covered with the protective film 19, resistance of the metal pattern 106a against corrosion can be improved.

### Second Preferred Embodiment

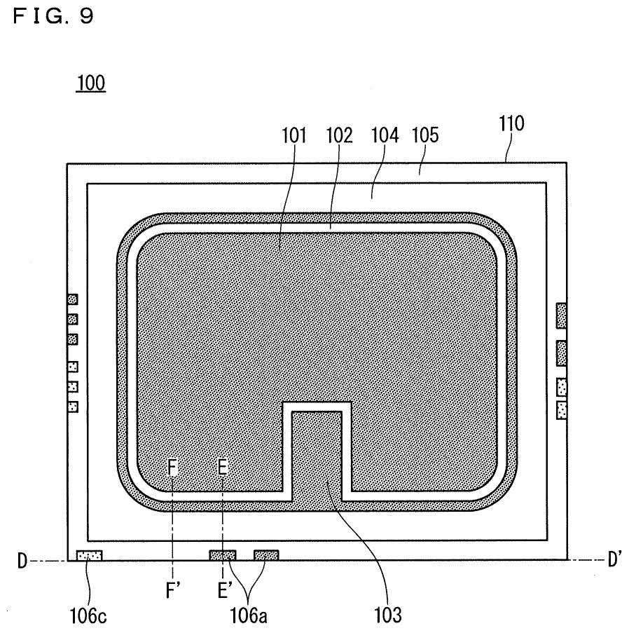

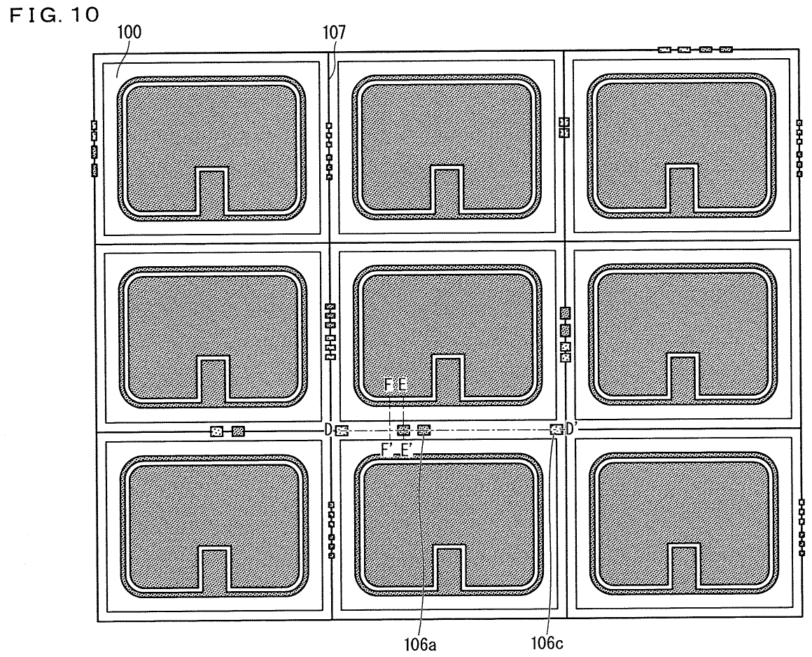

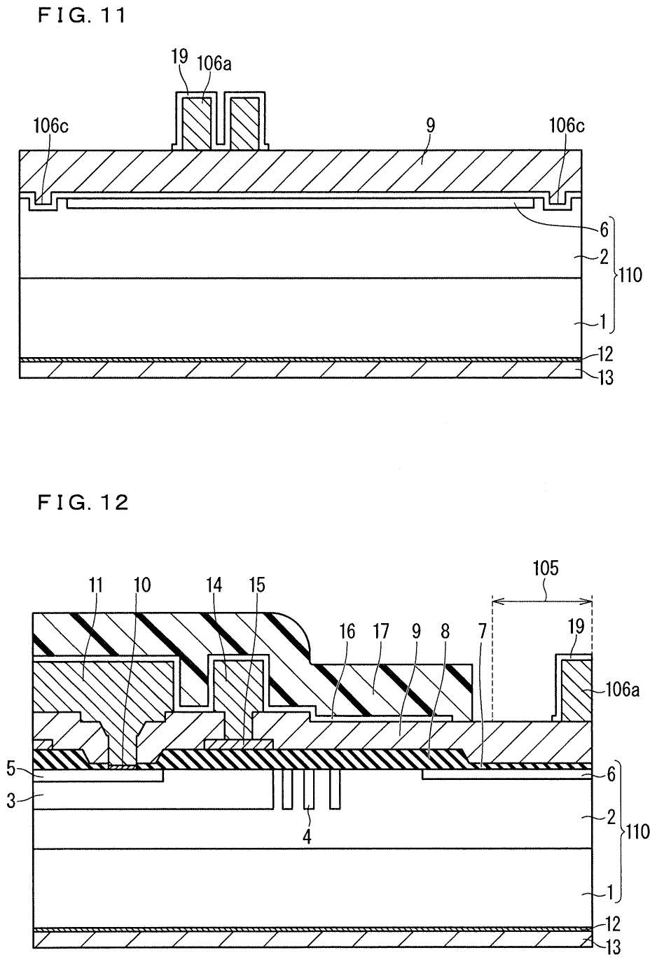

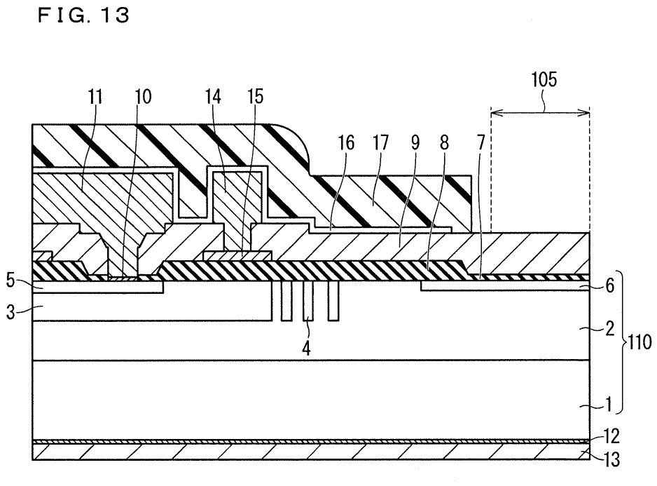

Next, a second preferred embodiment will be described. FIG. 9 is a top view of a semiconductor element 100 included in a semiconductor device according to the second preferred embodiment. FIG. 10 is an enlarged view corresponding to the region 202 in FIG. 1 in the second preferred embodiment. FIG. 11 is a cross-sectional view taken along line D-D′ in FIG. 9. FIG. 12 is a cross-sectional view taken along line E-E′ in FIG. 9. FIG. 13 is a cross-sectional view taken along line F-F′ in FIG. 9. In the second preferred embodiment, the same components as those described in the first preferred embodiment are denoted by the same reference numerals, and description thereof is omitted.

As illustrated in FIGS. 9 to 13, a first feature of the second preferred embodiment is that the dicing line region 105 and a groove pattern 106c as the manufacture-time reference pattern formed in the dicing line region 105 are covered with the interlayer insulating film 9, and the region in contact with the mold resin 26 corresponding to the groove pattern 106c is flattened.

A second feature of the second preferred embodiment is that the groove pattern 106c is arranged in at least one corner portion of the dicing line region 105.

A third feature of the second preferred embodiment is that the metal pattern 106a is arranged in the dicing line region 105 and is not arranged at the four corner portions of the dicing line region 105.

In the same procedure as in the first preferred embodiment, first, a groove pattern 106c is formed in the etching step, and then the metal pattern 106a is formed in the metal step.

As described above, in the second preferred embodiment, the groove pattern 106c is arranged in at least one corner portion of the dicing line region 105, and the region in contact with the mold resin 26 corresponding to the groove pattern 106c is planarized by the interlayer insulating film 9. Therefore, it is possible to improve the degree of freedom of arrangement of the groove pattern 106c while suppressing the groove pattern 106b from becoming a start point of peeling of the mold resin 26.

### Third Preferred Embodiment

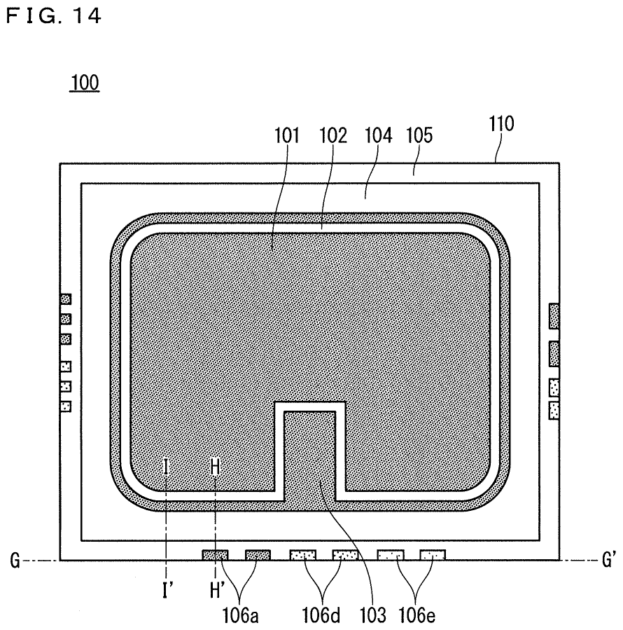

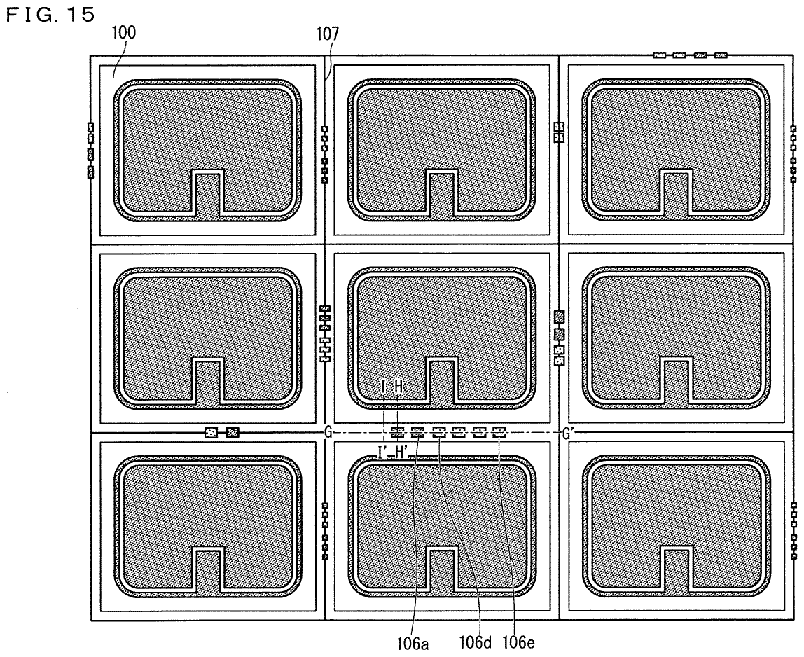

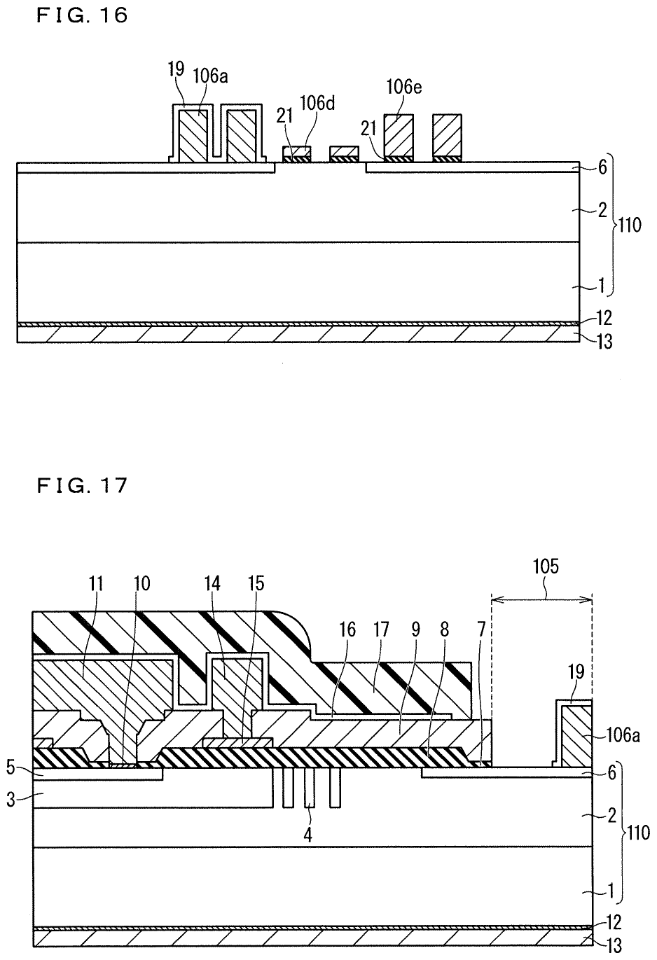

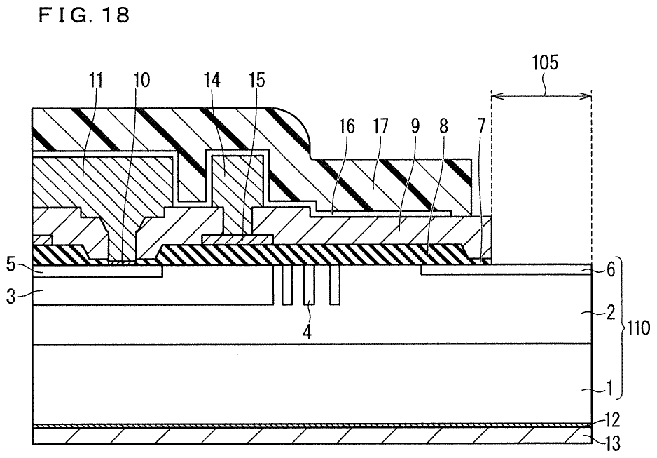

Next, a third preferred embodiment will be described. FIG. 14 is a top view of a semiconductor element 100 included in a semiconductor device according to the third preferred embodiment. FIG. 15 is an enlarged view corresponding to the region 202 in FIG. 1 in the third preferred embodiment. FIG. 16 is a cross-sectional view taken along line G-G′ in FIG. 14. FIG. 17 is a cross-sectional view taken along line H-H′ in FIG. 14. FIG. 18 is a cross-sectional view taken along line I-I′ in FIG. 14. In the third preferred embodiment, the same components as those described in the first and second preferred embodiments are denoted by the same reference numerals, and description thereof is omitted.

As illustrated in FIGS. 14 to 18, the feature of the third preferred embodiment is that a plurality of types of step shape patterns protruding upward from the upper surface of the semiconductor substrate 110 are arranged in addition to the metal pattern 106 as compared with the first preferred embodiment.

The plurality of types of step shape patterns include a polysilicon pattern 106d as a manufacture-time reference pattern using polysilicon often used in the gate structure of the MOSFET, and an insulating film pattern 106e as a manufacture-time reference pattern formed by etching the interlayer insulating film 9. The polysilicon pattern 106d and the insulating film pattern 106e are provided on the upper surface of the semiconductor substrate 110 via the insulating film 21, and each manufacture-time reference pattern includes an exposed portion. In particular, there is a case where the manufacture-time reference pattern is exposed from the organic protective film 17 due to the structure of the manufacture-time reference pattern. In this case, there is a possibility that a portion exposed from the organic protective film 17 is oxidized under conditions of high temperature and high humidity and the like, and this portion becomes a starting point of peeling.

As described above, in the third preferred embodiment, even in the case of patterns having different structures, such as a manufacture-time reference metal pattern, a manufacture-time reference pattern having an exposed portion, and a manufacture-time reference pattern having a portion protruding in a step shape, it is possible to suppress the pattern from becoming a starting point of peeling of the mold resin 26 by avoiding a corner portion of the dicing line region 105 as arrangement of the patterns.

### Fourth Preferred Embodiment

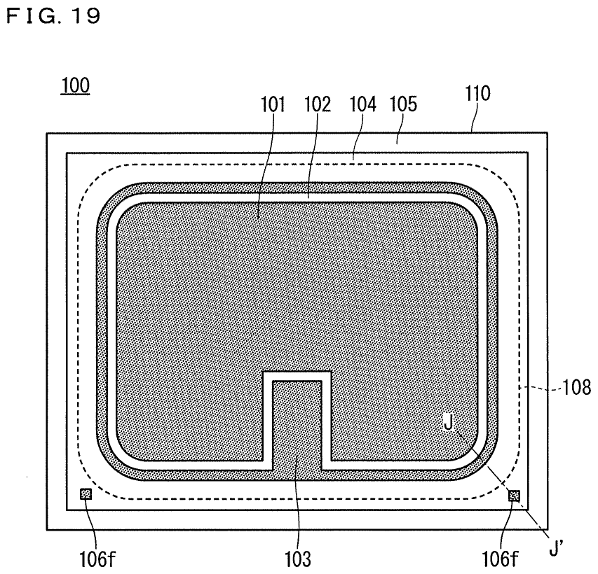

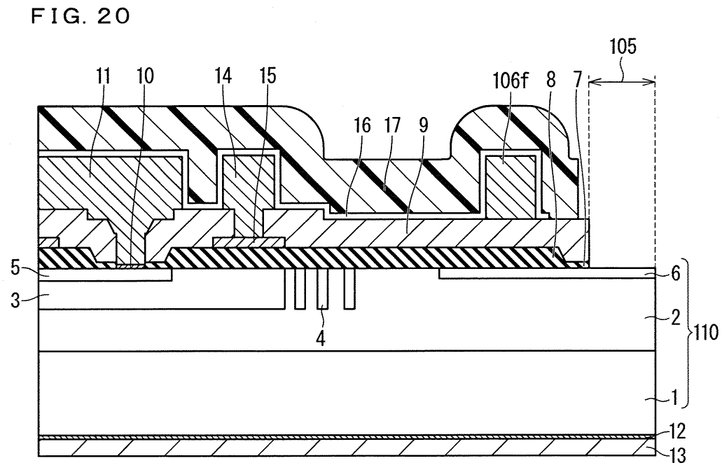

Next, a fourth preferred embodiment will be described. FIG. 19 is a top view of a semiconductor element 100 included in a semiconductor device according to the fourth preferred embodiment. FIG. 20 is a cross-sectional view taken along line J-J′ in FIG. 19. In the fourth preferred embodiment, the same components as those described in the first to third preferred embodiments are denoted by the same reference numerals, and description thereof is omitted.

As illustrated in FIGS. 19 and 20, the feature of the fourth preferred embodiment is that, in place of the metal pattern 106a and the groove pattern 106b, a metal pattern 106f as a manufacture-time reference metal pattern is provided not in the dicing line region 105 but on the upper surface of the semiconductor substrate 110 corresponding to the corner portion on the dicing line region 105 side in the termination region 104 and on the outer peripheral side of the depletion layer end portion formed in the termination region 104 when the maximum rated voltage is applied, as compared with the first preferred embodiment.

In FIG. 19, a dotted line indicated by 108 indicates a depletion layer end portion when the maximum rated voltage is applied. The outer peripheral side of the dotted line is basically at substantially the same potential as the applied voltage. Here, it is possible to design such that a distance (a width of a depleted region) from the source-side end portion of the termination region 104 to the depletion layer end portion 108 does not substantially change between a linear portion and a corner portion, and thus, the corner portion is wider than the linear portion. Therefore, in consideration of the distance on the outer peripheral side of the depletion layer end portion 108 and the size of the metal pattern 106f at the corner portion, the metal pattern 106f can be arranged at the corner portion. Since the outer peripheral side of the depletion layer end portion 108 is basically at the same potential as the applied voltage, the arrangement of the metal pattern 106f does not affect the electric field distribution in the termination region 104.

Furthermore, by arranging the step-shaped metal pattern 106f on the dicing line region 105 side in the termination region 104 instead of arranging the step-shaped metal pattern 106f on the dicing line region 105, it is possible to suppress application of a large stress to the end portion of the semiconductor element 100 including the corner portion of the semiconductor element 100. As a result, it is possible to suppress the metal pattern 106f from becoming a starting point of peeling of the mold resin 26.

The metal pattern 106f is covered with the insulating film 16 and the organic protective film 17. Here, the metal pattern 106f may be covered with at least one of the insulating film 16 or the organic protective film 17.

In addition, at the corner portion of the semiconductor element 100, since the termination structure which is the structure of the termination region 104 has a curvature, even if the metal pattern 106f is arranged on the upper surface of the semiconductor substrate 110 corresponding to the corner portion on the dicing line region 105 side in the termination region 104, it is easy to secure the distance between the metal pattern 106f and the termination structure of the semiconductor element 100. For example, even if electrical or mechanical migration occurs in the metal pattern 106f due to stress under a use environment of a product, an environmental test, or the like, the distance between the metal pattern 106f and the termination structure of the semiconductor element 100 is relatively easily secured, so that it is possible to minimize the influence of migration from reaching the termination structure of the semiconductor element 100.

Particularly, in the semiconductor element 100 in which silicon carbide (SiC) is used as the semiconductor material, it is often not necessary to arrange the annular wiring pattern on the outer peripheral portion of the termination region 104, and even if the metal pattern 106f is arranged on the upper surface of the semiconductor substrate 110 corresponding to the corner portion on the dicing line region 105 side in the termination region 104, a distance between the metal pattern 106f and the gate wiring 102 can be increased, so that a margin for peeling can be secured as much as possible without providing an excessive region.

In the semiconductor element 100 using silicon (Si) as a semiconductor material, in order to suppress the depletion layer from extending and reaching the dicing line 107 (see FIG. 3), there are often provided the n-channel stopper layer 6 and an annular wiring pattern thereon. However, when the distance between the wiring pattern and the metal pattern is short, peeling generated in the metal pattern progresses to the wiring pattern, so that peeling of the entire wiring pattern and peeling of the entire terminal structure are likely to occur.

On the other hand, in the fourth preferred embodiment, the semiconductor device includes the semiconductor element 100 having the semiconductor substrate 110 in which the active region 101 through which the main current flows, the termination region 104 which is a region on the outer peripheral side of the active region 101, and the dicing line region 105 which is a region on the outer peripheral side of the termination region 104 are defined. On the upper surface of the semiconductor substrate 110 corresponding to the corner portion on the dicing line region 105 side in the termination region 104 and on the outer peripheral side of the depletion layer end portion 108 formed in the termination region 104 when the maximum rated voltage is applied, the metal pattern 106f is provided, and the annular wiring pattern is not provided.

Therefore, since the metal pattern 106f is arranged in the termination region 104 while avoiding the dicing line region 105, it is possible to suppress application of a large stress to the end portion of the semiconductor element 100 including the corner portion of the semiconductor element 100. As a result, it is possible to suppress the metal pattern 106f from becoming a starting point of peeling of the mold resin 26 (see FIG. 7). In addition, since the distance between the metal pattern 106f and the termination structure of the semiconductor element 100 is relatively easily secured, it is possible to minimize the influence of migration from reaching the termination structure of the semiconductor element 100.

Furthermore, the metal pattern 106f is covered with at least one of the insulating film 16 or the organic protective film 17. Therefore, the metal pattern 106f can be suitably protected from the stress from the mold resin 26 (see FIG. 7).

Further, the insulating film 16 is made of at least one of a silicon oxide film or a silicon nitride film, and the organic protective film 17 is made of polyimide or polyamide. Therefore, the insulating film 16 and the organic protective film 17 can be formed in a general manufacturing step of a semiconductor device.

### Modification of Fourth Preferred Embodiment

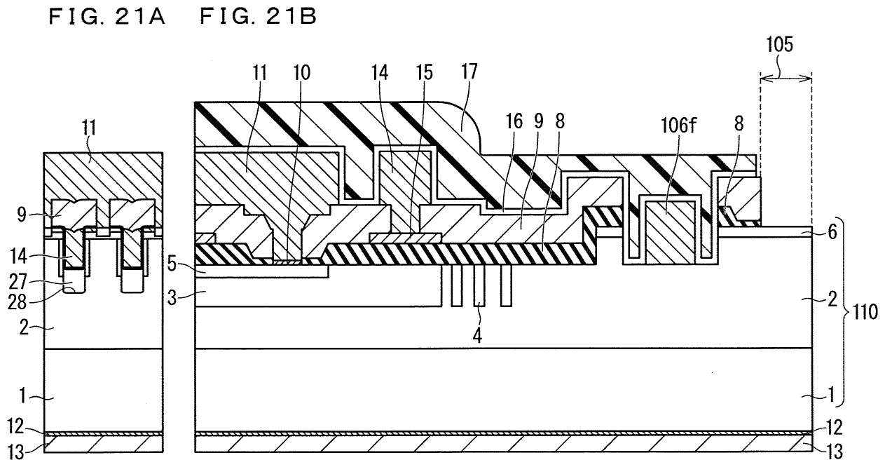

Next, a modification of the fourth preferred embodiment will be described. FIGS. 21A and 21B are cross-sectional views of the semiconductor element 100 included in the semiconductor device according to the first modification of the fourth preferred embodiment. Specifically, FIG. 21A is a cross-sectional view of the active region 101 of the semiconductor element 100, and FIG. 21B is a cross-sectional view of an end portion of the semiconductor element 100.

As illustrated in FIGS. 21A and 21B, the semiconductor element 100 is a trench gate type semiconductor element having the gate electrode 14 embedded in a trench 28 formed in the active region 101. A p-type diffusion layer 27 is provided at the bottom of the trench 28. The interlayer insulating film 9 is provided on the gate electrode 14. The source electrode 11 is provided on the interlayer insulating film 9.

The height position of the upper surface of the semiconductor substrate 110 in the termination region 104 is lower than the height position of the upper surface of the gate electrode 14. The metal pattern 106f is arranged on the upper surface of the semiconductor substrate 110 in the termination region 104 formed to have a height position lower than the upper surface of the gate electrode 14. This is because in a case where the trench gate type MOSFET structure is formed on the upper surface of the semiconductor element 100, the termination region 104 can have a structure in which the height position is lowered by the trench depth with respect to the upper surface of the gate electrode 14 of the active region 101. At this time, the height position around the wiring pattern is not lowered by the trench, so that the height position around the metal pattern 106f on the upper surface of the semiconductor substrate 110 is higher than the height position of the upper surface of the metal pattern 106f. Thus, the periphery of the metal pattern 106f can be surrounded by the semiconductor substrate 110.

As a result, since the metal pattern 106f does not directly receive the stress from the mold resin 26 (see FIG. 7), peeling of the mold resin 26 from the metal pattern 106f is less likely to occur. In addition, even in a case where the peeling of the mold resin 26 occurs, it is possible to suppress the progress of the peeling of the mold resin 26 due to the step of the semiconductor substrate 110, and thus, it is possible to more suitably suppress the peeling of the mold resin 26.

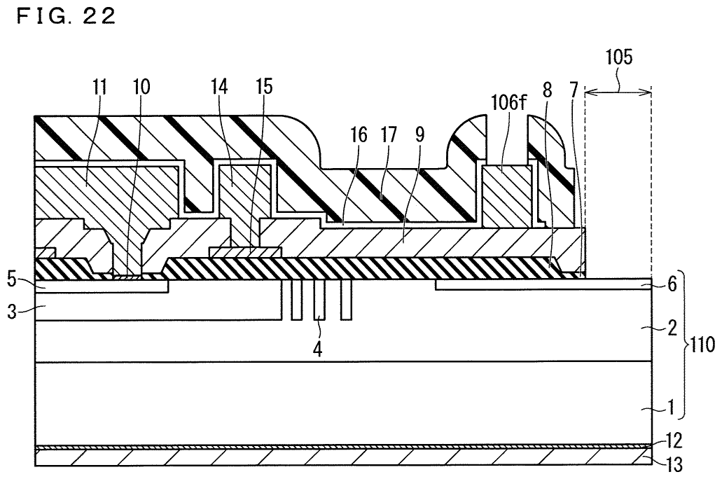

Next, a second modification of the fourth preferred embodiment will be described. FIG. 22 is a cross-sectional view of a semiconductor element 100 included in a semiconductor device according to the second modification of the fourth preferred embodiment.

As illustrated in FIG. 22, in the fourth preferred embodiment, since the metal patterns 106f are arranged at least at the corner portions at both ends of the linear portion of the termination region 104 where the gate pad region 103 as the control pad of the semiconductor element 100 is arranged, the metal pattern 106f can also be used as a recognition mark at the time of wire bonding.

After the semiconductor element 100 is mounted, the semiconductor element 100 is connected to a signal terminal by wire bonding. At this time, a wire bonding apparatus (not illustrated) detects positional information of the semiconductor element 100 to obtain a wire bonding position. Therefore, by arranging the metal patterns 106f functioning as recognition marks at the corner portions at both ends of the linear portion of the termination region 104 where the gate pad region 103 of the semiconductor element 100 is arranged, wire bonding accuracy can be improved.

As illustrated in FIG. 22, the semiconductor element 100 is provided with the insulating film 16 and the organic protective film 17 as protective films covering the active region 101 and the termination region 104 on the upper surface of the semiconductor substrate 110. At least a part of the upper surface of the metal pattern 106f is exposed from the insulating film 16 and the organic protective film 17. Therefore, the wire bonding apparatus can easily recognize the metal pattern 106f.

### Other Modifications

In the first to fourth preferred embodiments, it has been described that the MOSFET is adopted as the semiconductor element 100, but the present invention is not limited thereto, and another structure such as an IGBT or a diode may be adopted. In addition, it is possible to design to obtain an effect similar to that in a case where the polarity is not inverted even if the polarity is inverted. Furthermore, silicon (Si), silicon carbide (SiC), gallium nitride (GaN), or the like can also be used as the semiconductor material of the semiconductor element 100.

In addition, it is desirable that the metal patterns 106a are not arranged at the four corner portions of the dicing line region 105, but even when the metal pattern 106a is not arranged at least one corner portion, it is possible to suppress deterioration of peeling resistance and moisture resistance.

Note that the preferred embodiments can be freely combined, and the preferred embodiments can be appropriately modified or omitted.

Hereinafter, various aspects of the present disclosure will be collectively described as Appendices.

### (Appendix 1)

A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference metal pattern is provided on an upper surface of the semiconductor substrate in the dicing line region, and
the manufacture-time reference metal pattern is arranged in the dicing line region and is not arranged in at least one corner portion of the dicing line region.

### (Appendix 2)

The semiconductor device according to Appendix 1, wherein the manufacture-time reference metal pattern is not arranged at four corner portions of the dicing line region.

### (Appendix 3)

The semiconductor device according to Appendix 2, wherein the manufacture-time reference metal pattern is arranged in a linear portion of the dicing line region.

### (Appendix 4)

The semiconductor device according to any one of Appendixes 1 to 3, wherein the manufacture-time reference metal pattern is covered with a protective film.

### (Appendix 5)

A semiconductor device including a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference pattern having an exposed portion is provided on an upper surface of the semiconductor substrate in the dicing line region, and
the manufacture-time reference pattern is arranged in the dicing line region and is not arranged in at least one corner portion of the dicing line region.

### (Appendix 6)

The semiconductor device according to Appendix 5, wherein the manufacture-time reference pattern having the exposed portion is not arranged at four corner portions of the dicing line region.

### (Appendix 7)

The semiconductor device according to Appendix 6, wherein the manufacture-time reference pattern having the exposed portion is arranged in a linear portion of the dicing line region.

### (Appendix 8)

A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference pattern having a portion protruding in a step shape is provided on an upper surface of the semiconductor substrate in the dicing line region, and
the manufacture-time reference pattern is arranged in the dicing line region and is not arranged in at least one corner portion of the dicing line region.

### (Appendix 9)

The semiconductor device according to Appendix 8, wherein the manufacture-time reference pattern having the portion protruding in the step shape is not arranged at four corner portions of the dicing line region.

### (Appendix 10)

The semiconductor device according to Appendix 9, wherein the manufacture-time reference pattern having the portion protruding in the step shape is arranged in a linear portion of the dicing line region.

### (Appendix 11)

A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference metal pattern is provided on an upper surface of the semiconductor substrate corresponding to a corner portion on a side of the dicing line region in the termination region and on an outer peripheral side of a depletion layer end portion formed in the termination region when a maximum rated voltage is applied, and an annular wiring pattern is not provided.

### (Appendix 12)

The semiconductor device according to Appendix 11, wherein the manufacture-time reference metal pattern is covered with at least one of an insulating film or an organic protective film.

### (Appendix 13)

The semiconductor device according to Appendix 12, wherein the insulating film includes at least one of a silicon oxide film or a silicon nitride film.

### (Appendix 14)

The semiconductor device according to Appendix 12, wherein the organic protective film is made of polyimide or polyamide.

### (Appendix 15)

The semiconductor device according to any one of Appendixes 11 to 14, wherein
the semiconductor element is a trench gate type semiconductor element having a gate electrode embedded in a trench formed in the active region,
a height position of the upper surface of the semiconductor substrate in the termination region is lower than a height position of an upper surface of the gate electrode, and
the manufacture-time reference metal pattern is arranged on the upper surface of the semiconductor substrate in the termination region formed to have a height position lower than the upper surface of the gate electrode.

### (Appendix 16)

The semiconductor device according to any one of Appendixes 11 to 15, wherein a height position around the manufacture-time reference metal pattern on the upper surface of the semiconductor substrate is higher than a height position of an upper surface of the manufacture-time reference metal pattern.

### (Appendix 17)

The semiconductor device according to any one of Appendixes 11 to 16, wherein the manufacture-time reference metal pattern is arranged at least at the corner portions at both ends of a linear portion of the termination region where a control pad of the semiconductor element is arranged.

### (Appendix 18)

The semiconductor device according to Appendix 17, wherein the semiconductor element further includes a protective film that covers the active region and the termination region on the upper surface of the semiconductor substrate, and
at least a part of the upper surface of the manufacture-time reference metal pattern is exposed from the protective film.

### (Appendix 19)

A method of manufacturing the semiconductor device according to any one of Appendixes 1 to 4 or 11 to 18, the method including manufacturing the semiconductor device by performing a manufacturing step of the semiconductor device using the manufacture-time reference metal pattern.

### (Appendix 20)

A method of manufacturing the semiconductor device according to any one of Appendixes 5 to 10, the method including manufacturing the semiconductor device by performing a manufacturing step of the semiconductor device using the manufacture-time reference pattern.

While the disclosure has been shown and described in detail, the foregoing description is in all aspects illustrative and not restrictive. It is therefore understood that numerous modifications and variations can be devised.

What is claimed is:

1. A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference metal pattern is provided on an upper surface of the semiconductor substrate in the dicing line region, and
the manufacture-time reference metal pattern is arranged in the dicing line region and is not arranged in at least one corner portion of the dicing line region.

2. The semiconductor device according to claim 1, wherein the manufacture-time reference metal pattern is not arranged at four corner portions of the dicing line region.

3. The semiconductor device according to claim 2, wherein the manufacture-time reference metal pattern is arranged in a linear portion of the dicing line region.

4. The semiconductor device according to claim 1, wherein the manufacture-time reference metal pattern is covered with a protective film.

5. A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference pattern having an exposed portion is provided on an upper surface of the semiconductor substrate in the dicing line region, and
the manufacture-time reference pattern is arranged in the dicing line region and is not arranged in at least one corner portion of the dicing line region.

6. The semiconductor device according to claim 5, wherein the manufacture-time reference pattern having the exposed portion is not arranged at four corner portions of the dicing line region.

7. The semiconductor device according to claim 6, wherein the manufacture-time reference pattern having the exposed portion is arranged in a linear portion of the dicing line region.

8. A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference pattern having a portion protruding in a step shape is provided on an upper surface of the semiconductor substrate in the dicing line region, and
the manufacture-time reference pattern is arranged in the dicing line region and is not arranged in at least one corner portion of the dicing line region.

9. The semiconductor device according to claim 8, wherein the manufacture-time reference pattern having the portion protruding in the step shape is not arranged at four corner portions of the dicing line region.

10. The semiconductor device according to claim 9, wherein the manufacture-time reference pattern having the portion protruding in the step shape is arranged in a linear portion of the dicing line region.

11. A semiconductor device comprising a semiconductor element having a semiconductor substrate in which an active region through which a main current flows, a termination region that is a region on an outer peripheral side of the active region, and a dicing line region that is a region on an outer peripheral side of the termination region are defined, wherein
a manufacture-time reference metal pattern is provided on an upper surface of the semiconductor substrate corresponding to a corner portion on a side of the dicing line region in the termination region and on an outer peripheral side of a depletion layer end portion formed in the termination region when a maximum rated voltage is applied, and an annular wiring pattern is not provided.

12. The semiconductor device according to claim 11, wherein the manufacture-time reference metal pattern is covered with at least one of an insulating film or an organic protective film.

13. The semiconductor device according to claim 12, wherein the insulating film includes at least one of a silicon oxide film or a silicon nitride film.

14. The semiconductor device according to claim 12, wherein the organic protective film is made of polyimide or polyamide.

15. The semiconductor device according to claim 11, wherein
the semiconductor element is a trench gate type semiconductor element having a gate electrode embedded in a trench formed in the active region,
a height position of the upper surface of the semiconductor substrate in the termination region is lower than a height position of an upper surface of the gate electrode, and
the manufacture-time reference metal pattern is arranged on the upper surface of the semiconductor substrate in the termination region formed to have a height position lower than the upper surface of the gate electrode.

16. The semiconductor device according to claim 11, wherein a height position around the manufacture-time reference metal pattern on the upper surface of the semiconductor substrate is higher than a height position of an upper surface of the manufacture-time reference metal pattern.

17. The semiconductor device according to claim 11, wherein the manufacture-time reference metal pattern is arranged at least at the corner portions at both ends of a linear portion of the termination region where a control pad of the semiconductor element is arranged.

18. The semiconductor device according to claim 17, wherein
the semiconductor element further includes a protective film that covers the active region and the termination region on the upper surface of the semiconductor substrate, and
at least a part of the upper surface of the manufacture-time reference metal pattern is exposed from the protective film.

19. A method of manufacturing the semiconductor device according to claim 1, the method comprising manufacturing the semiconductor device by performing a manufacturing step of the semiconductor device using the manufacture-time reference metal pattern.

20. A method of manufacturing the semiconductor device according to claim 5, the method comprising manufacturing the semiconductor device by performing a manufacturing step of the semiconductor device using the manufacture-time reference pattern.

21. A method of manufacturing the semiconductor device according to claim 11, the method comprising manufacturing the semiconductor device by performing a manufacturing step of the semiconductor device using the manufacture-time reference metal pattern.

22. A method of manufacturing the semiconductor device according to claim 8, the method comprising manufacturing the semiconductor device by performing a manufacturing step of the semiconductor device using the manufacture-time reference pattern.
